(19) United States
(12) Patent Application Publication
(10) Pub. No.: US 2009/0020159 A1
(43) Pub. Date: Jan. 22, 2009

(54) DYE-SENSITIZED SOLAR CELL

(75) Inventors: Rong-Ho LEE, Min-Hsiung Township (TW); Yu-Wei HUANG, Jhong Li City (TW)

Correspondence Address: Workman Nydegger;1000 Eagle Gate Tower, 60 East South Temple, Salt Lake City, UT, 84111, US

(73) Assignee: National Yunlin University of Science and Technology, Douliou City (TW)

(21) Appl. No.: 11/849,615

(22) Filed: Sep. 4, 2007

(30) Foreign Application Priority Data
Jul. 19, 2007 (TW) 096126434

(51) Int. Cl. H01L 31/00

(52) U.S. Cl. 136/263; 136/252; 136/265

(57) ABSTRACT

A dye-sensitized solar cell includes a first electrode layer, a photosensitive dye layer, a second electrode layer, an energy-level intermediary layer, a first substrate and a second substrate. The photosensitive dye layer is used to receive sunlight and convert the sunlight to electrons and holes for being released. The first electrode layer is disposed on one side of the photosensitive dye layer to receive the electrons generated from the photosensitive dye layer. The second electrode layer is disposed on the other side of the photosensitive dye layer to receive the holes generated from the photosensitive dye layer. The energy-level intermediary layer is positioned between the first electrode layer and the photosensitive dye layer, so as to improve an injection efficiency of electrons and to prevent the generation of counter current, and thereby enhancing photoelectric conversion efficiency of the cell.

### BACKGROUND OF THE INVENTION

1. Field of the Invention

The present invention relates to a solar cell. More particularly, the present invention relates to a dye-sensitized solar cell.

2. Related Art

Due to the problems of global climate change, air pollution, and resource shortage, the possibility of taking solar cells as one of the main sources for power supply has widely drawn more and more attentions, which is exactly the reason for the rapid development of the market of silicon-based solar cells in recent years. The principle of the silicon-based solar cells is based on the photovoltaic effect of the semiconductor. Although the silicon solar cells have relatively high photoelectric conversion efficiency, as the manufacturing process is complicated and the cost is high, it is limited to some special applications. Therefore, many main research institutes all over the world are dedicated to the research of technologies relevant to solar energy, and expect to develop new materials capable of reducing the product cost and meanwhile improving the efficiency.

In the late 20^{th} century, a dye-sensitized solar cell is developed, which has advantages of low cost, light weight, flexible, and easy to be manufactured into a solar cell with a large area and so on. Accordingly, the dye-sensitized solar cell has gradually become a hot research issue in this field. In the dye-sensitized solar cell, a photosensitive dye is formed on a semiconductor electrode of a conductive substrate. When the photosensitive dye absorbs the sunlight, the photosensitive dye is excited by the light, and the electrons are transited to an excited state, but the excited state is not stable, the electrons are soon transferred to the semiconductor electrode. Afterwards, the electrons are dispersed to the conductive substrate, and transferred to the electrode via an external circuit. The dye in oxidization state is reduced by an electrolyte, and the oxidized electrolyte receives electrons at the counter electrode and reduced to a ground state, thus completing the electron transfer process.

One reason that influences the photoelectric conversion efficiency of the dye-sensitized solar cell lies in the efficiency for transferring and injecting the electrons to the conductive substrate after the photochemical reaction of the dye is excited. The electrons generated after the photosensitive dye is excited by the sunlight are transited to the electron transport layer and then transferred to the first electrode layer. In view of the above, how to effectively improve the efficiency of injecting the electrons to the first electrode layer, so as to improve the photoelectric conversion efficiency of the dye-sensitized solar cell also becomes one of the urgent problems to be solved by the researchers.

### SUMMARY OF THE INVENTION

In view of the above problems, the present invention is directed to a dye-sensitized solar cell, capable of improving the injection efficiency of electrons, so as to significantly improve the efficiency of the elements.

The present invention provides a dye-sensitized solar cell, which includes a photosensitive dye layer, a first electrode layer, a second electrode layer, an energy-level intermediary layer, a first substrate, and a second substrate. The photosensitive dye layer is used to receive the sunlight and transfer the sunlight to electrons and holes for being released. The first electrode layer is disposed on one side of the photosensitive dye layer to receive electrons generated from the photosensitive dye layer. The second electrode layer is disposed on the other side of the photosensitive dye layer opposite to the first electrode layer to receive the holes generated from the photosensitive dye layer. The energy-level intermediary layer is disposed between the first electrode layer and the photosensitive dye layer to improve the efficiency for transporting and injecting the electrons into the first electrode layer from the photosensitive dye layer. The first substrate is disposed on the other side of the first electrode layer opposite to the energy-level intermediary layer, and the second substrate is disposed on the other side of the second electrode layer opposite to the photosensitive dye layer.

In one embodiment of the present invention, an electron transport layer is further included, which is disposed between the first electrode layer and the photosensitive dye layer.

In another embodiment of the present invention, the electron transport layer is disposed between the energy-level intermediary layer and the photosensitive dye layer. Alternatively, the electron transport layer is further disposed between the first electrode layer and the energy-level intermediary layer according to the demands.

In an embodiment of the present invention, the energy-level intermediary layer can be a metal oxide layer. The material of the metal oxide layer can be sodium oxide (Na₂O), calcium oxide (CaO), magnesium oxide (MgO), alumina (Al₂O₃), zinc oxide (ZnO), ceria (CeO₂), zirconia (ZrO₂), or nickel oxide (NiO). Furthermore, the energy-level intermediary layer can also be a metal halide layer, which can be a metal fluoride layer or a metal chloride layer. The material of the metal fluoride layer can be, for example, lithium fluoride (LiF), cesium fluoride (CsF), sodium fluoride (NaF), magnesium fluoride (MgF₂), calcium fluoride (CaF₂), aluminum fluoride (AlF₃), barium fluoride (BaF₂), or strontium fluoride (SrF₂). The material of the metal chloride layer can be, for example, lithium chloride (LiCl), sodium chloride (NaCl), cesium chloride (CsCl), magnesium chloride (MgCl₂), calcium chloride (CaCl₂), aluminum chloride (AlCl₃), barium chloride (BaCl₂), strontium chloride (SrCl₂), or nickel chloride (NiCl₂). Alternatively, the energy-level intermediary layer can further be an organic metal complex layer, which can be metal acetate, metal carbonate, or metal nitrate. The metal acetate can be, for example, sodium acetate (Na(CH₃COO)), calcium acetate (Ca(CH₃COO)₂), magnesium acetate (Mg(CH₃COO)₂), cesium acetate (Cs(CH₃COO)), zinc acetate (Zn(CH₃COO)₂), cerium acetate (Ce(CH₃COO)₂), zirconium acetate (Zr(CH₃COO)₂), or nickel acetate (Ni(CH₃COO)₂); the metal carbonate can be, for example, sodium carbonate (Na₂CO₃), calcium carbonate (CaCO₃), magnesium carbonate (MgCO₃), cesium carbonate (Cs₂CO₃), nickel carbonate (NiCO₃), zinc carbonate (ZnCO₃), cerium carbonate (Ce(CO₃)₂), or zirconium carbonate (Zr(CO₃)₂); and the metal nitrate can be, for example, calcium nitrate (Ca(NO₃)₂), magnesium nitrate (Mg(NO₃)₂), cesium nitrate (CsNO₃), nickel nitrate (Ni(NO₃)₂), zinc nitrate (Zn(NO₃)₂), cesium nitrate (Ce(NO₃)₄), or zirconium nitrate (Zr(NO₃)₄).

In one embodiment of the present invention, an electrolyte is further included, which is disposed between the photosensitive dye layer and the second electrode layer. The electrolyte can be a liquid electrolyte, semi-solid electrolyte, or solid electrolyte.

In another embodiment of the present invention, a transparent electrode is further disposed between the second electrode layer and the second substrate according to the demands. The material of the transparent electrode is indium-tin oxide.

According to the dye-sensitized solar cell of the present invention, an energy-level intermediary layer is disposed between the first electrode layer and the photosensitive dye layer to improve the efficiency for transporting and injecting the electrons into the first electrode layer from the photosensitive dye layer. Particularly, when the photosensitive dye is excited by the sunlight, the electrons are transited to an excited state, and at this time, the electrons are effectively injected into the electron transport layer or the first electrode layer through the energy-level intermediary layer under the tunneling effect. The energy-level intermediary layer is of metal oxide or metal fluoride, which is evaporated on the surface of the electron transport layer, so as to enlarge the surface area of the electron transport layer, and thus improving the electron injection flux. The existence of the energy-level intermediary layer offers the chance to prevent the electrons already injected into the electron transport layer from coming back into the dye layer, and thus inhibiting the generation of the counter current. In this way, the injection efficiency of electrons can be effectively improved, and thus, the efficiency of the elements is also improved.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, which thus is not limitative of the present invention, and wherein:

FIG. 1 is a schematic cross-sectional view of a structure of a dye-sensitized solar cell according to the present invention.

FIG. 2 is a schematic cross-sectional view of a structure of another dye-sensitized solar cell according to the present invention.

FIG. 3 shows current-voltage relation curves of a dye-sensitized solar cell containing calcium oxide of the present invention and a common dye-sensitized solar cell obtained through testing.

FIG. 4 shows current-voltage relation curves of a dye-sensitized solar cell containing lithium fluoride of the present invention and a common dye-sensitized solar cell obtained through testing.

### DETAILED DESCRIPTION OF THE INVENTION

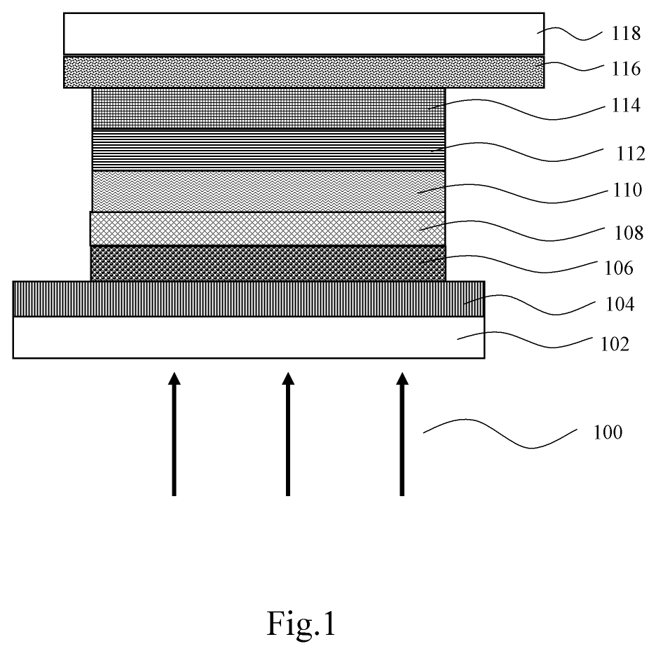

Referring to FIG. 1, it is a schematic cross-sectional view of a structure of a dye-sensitized solar cell according to the present invention. As shown in FIG. 1, the dye-sensitized solar cell sequentially includes a first substrate 102, a first electrode layer 104, an electron transport layer 106, an energy-level intermediary layer 108, a photosensitive dye layer 110, an electrolyte 112, a second electrode layer 114, a transparent electrode 116, and a second substrate 118.

In an embodiment of the present invention, the first electrode layer 104 is a transparent conductive glass, and the material of the transparent conductive glass is a glass with a conductive film of fluorine-doped tin dioxide (SnO₂: F) or indium-tin oxide (ITO) plated thereon.

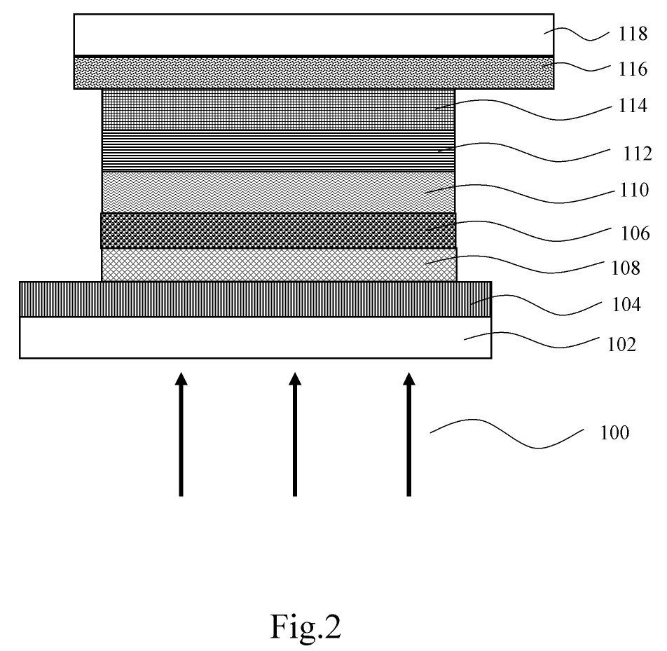

In this embodiment, the electron transport layer 106 is disposed between the first electrode layer 104 and the energy-level intermediary layer 108, and the electron transport layer 106 is made of titanium dioxide (TiO₂). Alternatively, the electron transport layer 106 is further disposed between the photosensitive dye layer 110 and the energy-level intermediary layer 108, as shown in FIG. 2.

In an embodiment of the present invention, the energy-level intermediary layer 108 can be, but not limited to, a metal oxide layer. The material of the metal oxide layer can be sodium oxide (Na₂O), calcium oxide (CaO), magnesium oxide (MgO), alumina (Al₂O₃), zinc oxide (ZnO), ceria (CeO₂), zirconia (ZrO₂), or nickel oxide (NiO). Alternatively, the energy-level intermediary layer 108 can also be a metal halide layer, which can be a metal fluoride layer or a metal chloride layer. The material of the metal fluoride layer can be, for example, lithium fluoride (LiF), cesium fluoride (CsF), sodium fluoride (NaF), magnesium fluoride (MgF₂), calcium fluoride (CaF₂), aluminum fluoride (AlF₃), barium fluoride (BaF₂), or strontium fluoride(SrF₂); the material of the metal chloride layer can be, for example, lithium chloride (LiCl), sodium chloride (NaCl), cesium chloride (CsCl), magnesium chloride (MgCl₂), calcium chloride (CaCl₂), aluminum chloride (AlCl₃), barium chloride (BaCl₂), strontium chloride (SrCl₂), or nickel chloride(NiCl₂). Alternatively, the energy-level intermediary layer 108 can further be an organic metal complex layer, which can be of metal acetate, metal carbonate, or metal nitrate. The metal acetate can be, for example, sodium acetate (Na(CH₃COO)), calcium acetate (Ca(CH₃COO)₂), magnesium acetate (Mg(CH₃COO)₂), cesium acetate (Cs(CH₃COO)), zinc acetate (Zn(CH₃COO)₂), cerium acetate (Ce(CH₃COO)₂), zirconium acetate (Zr(CH₃COO)₂), or nickel acetate (Ni(CH₃COO)₂); the metal carbonate can be, for example, sodium carbonate (Na₂CO₃), calcium carbonate (CaCO₃), magnesium carbonate (MgCO₃), cesium carbonate (Cs₂CO₃), nickel carbonate (NiCO₃), zinc carbonate (ZnCO₃), cerium carbonate (Ce(CO₃)₂), or zirconium carbonate (Zr(CO₃)₂); the metal nitrate can be, for example, calcium nitrate (Ca(NO₃)₂), magnesium nitrate (Mg(NO₃)₂), cesium nitrate (CsNO₃), nickel nitrate (Ni(NO₃)₂), zinc nitrate (Zn(NO₃)₂), cesium nitrate (Ce(NO₃)₄), or zirconium nitrate (Zr(NO₃)₄). The materials of the energy-level intermediary layer 108 are not intended to limit the scope of the present invention.

In an embodiment of the present invention, the above metal oxide layer serving as the energy-level intermediary layer 108 can be formed through the following steps. Firstly, a metal film is formed through a vacuum evaporation process; next, an oxygen gas is charged therein for oxidizing the metal film into the metal oxide. Alternatively, in another embodiment of the present invention, the metal oxide can be formed through using the organic metal complex (for example, metal acetate, metal carbonate, or metal nitrate) by the following steps. Firstly, the organic metal complex is coated on the conductive glass layer or titanium dioxide layer; next, after it is formed into a film upon being dried, an oxygen gas is charged therein; then, the film is heated to a high temperature (for example, over 400° C.), so that the organic metal complex is oxidative cracked, so as to form the metal oxide.

In an embodiment of the present invention, the metal halide layer, such as the metal fluoride layer and the metal chloride layer, serving as the energy-level intermediary layer 108, can be formed through vacuum evaporation process.

In an embodiment of the present invention, the process of preparing the organic metal complex layer serving as the energy-level intermediary layer 108 includes the following steps: dissolving and dispersing an organic metal complex, for example, metal acetate, metal carbonate, or metal nitrate, in an alcohol (for example, methanol, ethanol, or isopropanol) in a proper weight percentage; next, the solution is coated on a conductive glass layer or titanium dioxide layer through spin coating, so as to form a film thereon; then, after coating, the film is dried by vacuum or heating, so as to complete the preparation of the organic metal complex layer serving as the energy-level intermediary layer 108.

In an embodiment of the present invention, the material of the photosensitive dye layer 110 can be N3 dye, N719 dye, or black dye. The N3 dye has a chemical formula of [cis-di(thiocyanato)-bis(2,2′-bipyridyl-4,4′-dicarboxylic acid)-ruthenium(II)], N719 dye has a chemical formula of [cis-di(thiocyanato)-bis(2,2′-bipyridyl-4-carboxylate-4′-carboxylic acid)-ruthenium(II)], the N712 dye has a chemical formula of (Bu₄N)₄[Ru(dcbpy)₂(NCS)₂] (Bu₄N=tetrabutyl-ammonium and dcbpyH₂=2,2′-bipyridyl-4,4′-dicarboxylic acid), and the black dye has a chemical formula of [(tri(cyanato)-2,2′,2″-terpy-ridyl-4,4′,4″-tri-carboxylate)Ru(II)].

In this embodiment, the electrolyte 112 is disposed between the photosensitive dye layer 110 and the second electrode layer 114. The electrolyte can be a liquid electrolyte, semi-solid electrolyte, or solid electrolyte.

The transparent electrode 116 is disposed between the second electrode layer 114 and the second substrate 118. The transparent electrode 116 is made of indium-tin oxide.

The first substrate 102 and the second substrate 118 can be a transparent glass or a transparent plastic respectively. The transparent plastic is made of poly-ethyleneterephthalate, polyester, polycarbonates, polyacrylates, or polystyrene.

Therefore, when the sunlight 100 irradiates the dye-sensitized solar cell of the present invention, the photosensitive dye layer 110 is excited by the sunlight 100, such that the electrons are transited to an excited state. Meanwhile, as an energy-level intermediary layer 108 exists between the first electrode layer 104 and the photosensitive dye layer 110, the excited electrons penetrate through the energy-level intermediary layer 108, and they are firstly transported to the energy-level intermediary layer 108 from the photosensitive dye layer 110, and then transferred to the first electrode layer 104 from the energy-level intermediary layer 108. That is to say, in the present invention, an energy-level intermediary layer 108 is disposed between the photosensitive dye layer 110 and the first electrode layer 104, and the energy-level intermediary layer 108 existed between the photosensitive dye layer 110 and the first electrode layer 104 can effectively improve the injection efficiency of electrons and allow the electrons to be rapidly transferred onto the first electrode layer 104. Therefore, not only the injection efficiency of electrons is improved, but the efficiency of the elements is also improved.

Referring to FIG. 1 again, in one preferred embodiment of the present invention, the process of preparing the dye-sensitized solar cell includes the following steps: firstly, a transparent conductive glass is taken as the first electrode layer 104; next, a titanium dioxide layer is coated on the first electrode layer 104 through a screen printing process, to serve as the electron transport layer 106; afterwards, a calcium layer is plated on the electron transport layer 106, in which the calcium layer has a thickness of about 10 Å; then, an oxygen gas is charged therein to oxidize the calcium layer, so as to form a calcium oxide layer, and thus completing the preparation of the energy-level intermediary layer 108.

Subsequently, the energy-level intermediary layer 108 is immersed in a N719 dye solution serving as the photosensitive dye layer 110, and heated and dried, so that the N719 dye is absorbed on the surface of the energy-level intermediary layer 108. Finally, an electrolyte 112 is formed, and Pt is used as the second electrode layer 116. In such manner, the preparation of the dye-sensitized solar cell containing calcium oxide is completed.

Afterwards, the element test is performed. Firstly, the dye-sensitized solar cell is irradiated by a simulated sunlight with an intensity of about 100 mW/cm². Then, the open-circuit voltage (Voc), the short-circuit current (Jsc), the fill factor (FF), and the photoelectric conversion efficiency (η, %) of the element after irradiation are measured, and the test results are described below. The fill factor (FF) is defined as the ratio of the maximum power divided by the open-circuit voltage and the short-circuit current, and the photoelectric conversion efficiency (η) refers to the percentage of the energy collected upon converting lights into electricity to the input optical power.

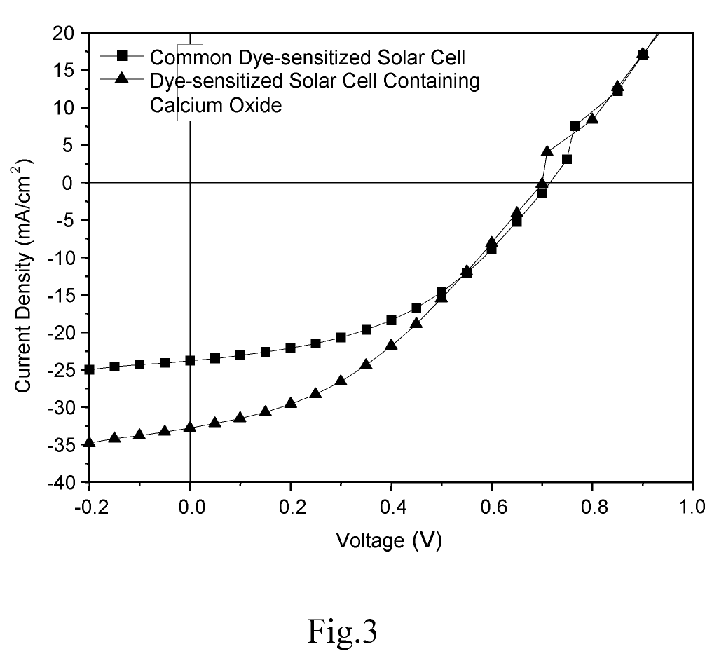

Referring to FIG. 3, it shows current-voltage relation curves of a dye-sensitized solar cell containing calcium oxide of the present invention and a common dye-sensitized solar cell obtained through testing. Referring to FIG. 3 and Table 1 together, compared with common dye-sensitized solar cells without a calcium oxide layer, the existence of the calcium oxide layer dose not make significant changes to the open-circuit voltage of the dye-sensitized solar cell, which is still maintained at about 0.70 V, the short-circuit current is increased to about 32.83 mA/cm². After calculation, the fill factor (FF) is about 0.38, and the photoelectric conversion efficiency is increased up to about 8.74%. Therefore, it can be known from the experimental data that, when the photosensitive dye layer 110 is excited by the sunlight, the tunneling effect of the electrons is increased through the electron injection area provided by the calcium oxide layer, and thus, the efficiency of injecting the electrons into the first electrode layer 104 is also increased. In such a manner, the photoelectric conversion efficiency reaches up to about 8.74%.

TABLE 1
Relation between the Common Dye-sensitized Solar Cell and
Dye-sensitized Solar Cell Containing Calcium Oxide

| | Common | Dye-sensitized |
|---|---|---|
| | Dye-sensitized | Solar Cell |
| | Solar Cell | Containing Calcium Oxide |
| Open-circuit Voltage (V) | 0.70 | 0.70 |
| Short-circuit Current | 23.75 | 32.83 |
| (mA/cm²) | | |
| Fill Factor (FF) | 0.45 | 0.38 |
| Photoelectric Conversion | 7.54 | 8.74 |
| Efficiency (%) | | |

Alternatively, lithium fluoride can also be used as the energy-level intermediary layer 108 according to the demands. As for the process of preparing the dye-sensitized solar cell containing lithium fluoride is as that described above, which thus will not be described in detail herein.

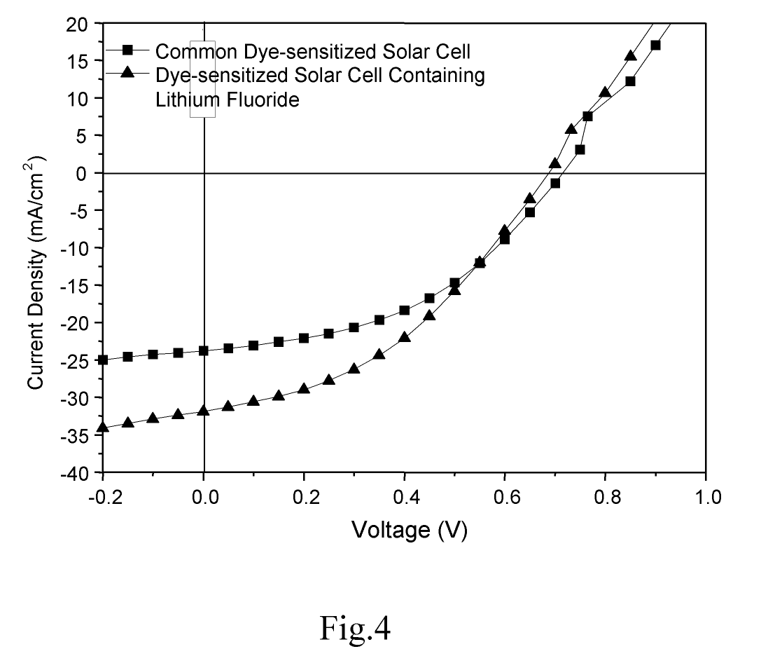

Afterwards, as described above, the dye-sensitized solar cell containing lithium fluoride is tested, and the test results are shown in FIG. 4. Referring to FIG. 4 and Table 2 together, compared with the common dye-sensitized solar cells without containing a lithium fluoride layer, the open-circuit voltage of the dye-sensitized solar cell containing lithium fluoride is still maintained at about 0.70 V, and the short-circuit current is increased to 31.87 mA/cm². After calculation, the fill factor (FF) is about 0.40 and the photoelectric conversion efficiency reaches up to about 8.84%. Therefore, it can be known from the experimental data that, when the photosensitive dye layer 110 is excited by the sunlight, the tunneling effect of electrons is increased through the electron injection area provided by the lithium fluoride layer, thus improving the efficiency of injecting the electrons into the first electrode layer 104. In such manner, the photoelectric conversion efficiency is increased up to about 8.84%.

TABLE 2
Relation between the Common Dye-sensitized Solar Cell and
Dye-sensitized Solar Cell Containing Lithium Fluoride

| | Common | Dye-sensitized |
|---|---|---|
| | Dye-sensitized | Solar Cell |
| | Solar Cell | Containing Lithium Fluoride |
| Open-circuit Voltage (V) | 0.70 | 0.70 |
| Short-circuit Current | 23.75 | 31.87 |
| (mA/cm²) | | |
| Fill Factor (FF) | 0.45 | 0.40 |
| Photoelectric Conversion | 7.54 | 8.84 |
| Efficiency (%) | | |

In view of above, it can be know from the test results that, the dye-sensitized solar cell of the present invention has relatively high photoelectric conversion efficiency. Furthermore, in the present invention, an energy-level intermediary layer is disposed between the first electrode layer and the photosensitive dye layer to effectively improve the electron transition rate, and thus significantly enhancing the efficiency of the elements.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A dye-sensitized solar cell, comprising a photosensitive dye layer, for receiving sunlight and converting the sunlight into a plurality of electrons and a plurality of holes for being released;
a first electrode layer, disposed on one side of the photosensitive dye layer, for receiving the electrons generated from the photosensitive dye layer;
a second electrode layer, disposed on the other side of the photosensitive dye layer opposite to the first electrode layer, for receiving the holes generated from the photosensitive dye layer;
an energy-level intermediary layer, disposed between the first electrode layer and the photosensitive dye layer, for improving the electrons injection and transport efficiency between the first electrode layer and the photosensitive dye layer;
a first substrate, disposed on the other side of the first electrode layer opposite to the energy-level intermediary layer; and
a second substrate, disposed on the other side of the second electrode layer opposite to the photosensitive dye layer.

2. The dye-sensitized solar cell as claimed in claim 1, further comprising an electron transport layer, disposed between the first electrode layer and the photosensitive dye layer.

3. The dye-sensitized solar cell as claimed in claim 2, wherein the electron transport layer is disposed between the energy-level intermediary layer and the photosensitive dye layer.

4. The dye-sensitized solar cell as claimed in claim 2, wherein the electron transport layer is disposed between the first electrode layer and the energy-level intermediary layer.

5. The dye-sensitized solar cell as claimed in claim 1, wherein the energy-level intermediary layer is a metal oxide layer.

6. The dye-sensitized solar cell as claimed in claim 5, wherein the material of the metal oxide layer is one selected from a group consisting of sodium oxide (Na₂O), calcium oxide (CaO), magnesium oxide (MgO), alumina (Al₂O₃), zinc oxide (ZnO), ceria (CeO₂), zirconia (ZrO₂), and nickel oxide (NiO).

7. The dye-sensitized solar cell as claimed in claim 1, wherein the energy-level intermediary layer is a metal halide layer.

8. The dye-sensitized solar cell as claimed in claim 7, wherein the metal halide layer is a metal fluoride layer.

9. The dye-sensitized solar cell as claimed in claim 8, wherein the material of the metal fluoride layer is one selected from a group consisting of lithium fluoride (LiF), cesium fluoride (CsF), sodium fluoride (NaF), magnesium fluoride (MgF₂), calcium fluoride (CaF₂), aluminum fluoride (AlF₃), barium fluoride (BaF₂), and strontium fluoride(SrF₂).

10. The dye-sensitized solar cell as claimed in claim 7, wherein the metal halide layer is a metal chloride layer.

11. The dye-sensitized solar cell as claimed in claim 10, wherein the material of the metal chloride layer is one selected from a group consisting of lithium chloride (LiCl), sodium chloride (NaCl), cesium chloride (CsCl), magnesium chloride (MgCl₂), calcium chloride (CaCl₂), aluminum chloride (AlCl₃), barium chloride (BaCl₂), strontium chloride (SrCl₂), and nickel chloride(NiCl₂).

12. The dye-sensitized solar cell as claimed in claim 1, wherein the energy-level intermediary layer is an organic metal complex layer.

13. The dye-sensitized solar cell as claimed in claim 12, wherein the organic metal complex layer is of metal acetate, metal carbonate, or metal nitrate.

14. The dye-sensitized solar cell as claimed in claim 13, wherein the material of the metal acetate is one selected from the group consisting of sodium acetate (Na(CH₃COO)), calcium acetate (Ca(CH₃COO)₂), magnesium acetate (Mg(CH₃COO)₂), cesium acetate (Cs(CH₃COO)), zinc acetate (Zn(CH₃COO)₂), cerium acetate (Ce(CH₃COO)₂), zirconium acetate (Zr(CH₃COO)₂), and nickel acetate (Ni(CH₃COO)₂).

15. The dye-sensitized solar cell as claimed in claim 13, wherein the material of the metal carbonate is one selected from a group consisting of sodium carbonate (Na₂CO₃), calcium carbonate (CaCO₃), magnesium carbonate (MgCO₃), cesium carbonate (Cs₂CO₃), nickel carbonate (NiCO₃), zinc carbonate (ZnCO₃), cerium carbonate (Ce(CO₃)₂), and zirconium carbonate (Zr(CO₃)₂).

16. The dye-sensitized solar cell as claimed in claim 13, wherein the material of the metal nitrate is one selected from a group consisting of calcium nitrate (Ca(NO₃)₂), magnesium nitrate (Mg(NO₃)₂), cesium nitrate (CsNO₃), nickel nitrate (Ni(NO₃)₂), zinc nitrate (Zn(NO₃)₂), cesium nitrate (Ce(NO₃)₄), and zirconium nitrate (Zr(NO₃)₄).

17. The dye-sensitized solar cell as claimed in claim 1, further comprising an electrolyte disposed between the photosensitive dye layer and the second electrode layer.

18. The dye-sensitized solar cell as claimed in claim 17, wherein the electrolyte is a liquid electrolyte, semi-solid electrolyte, or solid electrolyte.

19. The dye-sensitized solar cell as claimed in claim 1, further comprising a transparent electrode, disposed between the second electrode layer and the second substrate.

20. The dye-sensitized solar cell as claimed in claim 19, wherein the material of the transparent electrode is indium-tin oxide.
